(19) United States
(12) Patent Application Publication
(10) Pub. No.: US 2009/0115002 A1
(43) Pub. Date: May 7, 2009

(54) Semiconductor Device

(75) Inventors: Tooru Tatsumi, Tokyo (JP); Masayuki Terai, Tokyo (JP); Takashi Hase, Tokyo (JP); Kensuke Takahashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC CORPORATION, Tokyo (JP)

(21) Appl. No.: 11/922,605

(22) PCT Filed: Jun. 20, 2006
(86) PCT No.: PCT/JP2006/312273

§ 371 Date: Dec. 20, 2007

(30) Foreign Application Priority Data
Jun. 23, 2005 (JP) 2005-183518

(51) Int. Cl. H01L 29/78

(52) U.S. Cl. 257/412; 257/E29.255

(57) ABSTRACT

There is provided a semiconductor device including: a first field effect transistor region including a gate insulating film, a gate electrode and gate sidewalls formed in a P channel forming region; and a second field effect transistor region including a gate insulating film, a gate electrode and gate sidewalls formed in an N channel forming region on a semiconductor substrate, wherein in the first and second field effect transistor regions, the gate electrodes are composed primarily of a silicide of metal M represented as M(x)Si(1−x)(0<x<1) and satisfy t1−t2<L/2, wherein the height of the gate electrodes is t1, the height of the gate sidewalls is t2 and the gate length of the gate electrodes is L; and the height of the gate electrode in the P channel forming region is greater than the height of the gate electrode in the N channel forming region.

### TECHNICAL FIELD

The present invention relates to a semiconductor device including a high-dielectric constant insulating film and a metal gate and, more particularly, to a technique for enhancing the performance and reliability of a metal oxide semiconductor field effect transistor (MOSFET).

### RELATED ART

In the development of an advanced complementary MOS (CMOS) device the transistors of which are being increasingly miniaturized, the degradation of drive currents due to the depletion of polysilicon (poly-Si) electrodes and the increase of gate leak currents due to the thin-filming of a gate insulating film have become problematic. Hence, combined techniques are under study to avoid electrode depletion by adopting metal gate electrodes, as well as to reduce gate leak currents by thickening physical film thicknesses using a high-dielectric constant material for the gate insulating film. As a material to be used for the metal gate electrodes, pure metal, metal nitrides, silicides and the like are under consideration. In either case, it must be possible to set the threshold voltage (Vth) of an N-type MOSFET and a P-type MOSFET to a correct value. In order to realize a value of “Vth” no greater than ±0.5 eV with a CMOS transistor, a material with a work function no greater than the mid-gap (4.6 eV) of Si, preferably 4.4 eV or smaller, needs to be used for the gate electrodes in the case of the N-type MOSFET. In contrast, a material with a work function no smaller than the mid-gap (4.6 eV) of Si, preferably 4.8 eV or larger, needs to be used for the gate electrodes in the case of the P-type MOSFET.

On the other hand, mobility has been improved by controlling stresses applied to channel regions for the CMOSFETs of the 90 nm node or later, which is now a technique as important as the metal gate technology. As a typical example, Document 1 (International Electron Devices Meeting Technical Digest 2003, p. 73) discloses a technique wherein the operating speed of a transistor is improved by 5 to 10% by controlling the stress of deposition films covering electrode silicides, element-isolating regions, gate electrodes and the side walls thereof. It has been reported that if a uniaxial tensile stress is applied in the gate length direction of the transistor, the channel direction of which is [110] on the (001) surface, the mobility of an N-type channel increases whereas the mobility of a P-type channel decreases. Accordingly, it is important to avoid inducing mobility degradation due to stresses also when applying metal gate electrodes to the CMOSFETs.

As means for realizing the above-described CMOS device, there has been proposed a method of controlling the “Vth” of a transistor by selectively using different types of metal having different work functions, or their alloys, for an N-type MOSFET and a P-type MOSFET (dual metal gate technology), as shown in FIG. 2a. For example, Document 2 (International Electron Devices Meeting Technical Digest 2002, p. 359) states that the work functions of Ta and Ru formed on SiO₂ are 4.15 eV and 4.95 eV, respectively, and thus the modulation of a work function of 0.8 eV is possible between these two electrodes. Note here that reference numeral 1 in FIG. 2a denotes a silicon substrate, reference numeral 2 denotes an element-isolating region, reference numeral 106 denotes an extended diffusion region, reference numeral 108 denotes a source/drain diffusion region, reference numeral 110 denotes a source/drain silicide layer, reference numeral 111 denotes an insulating film, reference numeral 125 denotes Ta metal, reference numeral 126 denotes Ru metal, reference numeral 127 denotes W metal, reference numeral 128 denotes an SiO₂ insulating film, and reference numeral 129 denotes a gate sidewall.

In addition, a technique related to a silicide electrode obtained by completely siliciding a poly-Si electrode with Ni, Hf, W or the like has become a focus of attention recently. For example, Document 3 (International Electron Devices Meeting Technical Digest 2002, p. 247) and Document 4 (International Electron Devices Meeting Technical Digest 2003, p. 315) disclose a technique to modulate electrode work functions by up to 0.5 eV, by using SiO₂ for the gate insulating film and by using, as the gate electrodes, Ni silicide electrodes (P-doped NiSi and B-doped NiSi), such as those shown in FIG. 2b, obtained by completely siliciding poly-Si electrodes implanted with such impurities as P and B, with Ni. This technique features the advantage that the poly-Si electrodes can be silicided after carrying out high-temperature heat treatment to activate impurities in the source/drain diffusion region of the CMOS device and, therefore, has a high degree of consistency with conventional CMOS processes. Note that in FIG. 2b, reference numeral 1 denotes a silicon substrate, reference numeral 2 denotes an element-isolating region, reference numeral 106 denotes an extended diffusion region, reference numeral 107 denotes a gate sidewall, reference numeral 108 denotes a source/drain diffusion region, reference numeral 110 denotes a source/drain silicide layer, reference numeral 111 denotes a insulating film, reference numeral 117 denotes an SiO₂ gate insulating film, and reference numerals 123 and 124 denote Ni silicide gate electrodes.

In addition, Document 5 (International Electron Devices Meeting Technical Digest 2004, p. 83) shows that in a case where HfOx(N) is used as the gate insulating film, the effective work functions of Ni and Pt silicides hardly change even if such an impurity as Sb or B is implanted. In order to solve this problem, the document discloses a method of forming a CMOS by using HfOx(N) as the gate insulating film, N+ polysilicon as gate of an N-type MOSFET and PtSi as the gate of a P-type MOSFET, as shown in FIG. 2c, showing that the “Vth” of a PMOS is 0.39 V and the “Vth” of an NMOS is 0.08 V. The document further shows that if HfOx(N) is used as the gate insulating film, the effective work function changes from 4.6 eV, which is the mid-gap, to 4.8 eV suited for the PMOS when the ratio of Pt to Si is changed from Pt:Si=1:1 to Pt:Si=10:1. As the reason for this, the document states that if a silicide electrode having a high metal concentration is formed on HfON provided as a high-dielectric constant insulating film, the effect of Fermi-level pinning arising at the poly-Si/HfON interface prior to silicidation is eliminated, thereby allowing the virtually intrinsic work function value of the silicide to be reflected in the gate electrode. Note that in FIG. 2c, reference numeral 1 denotes a silicon substrate, reference numeral 2 denotes an element-isolating region, reference numeral 106 denotes an extended diffusion region, reference numeral 107 denotes a gate sidewall, reference numeral 108 denotes a source/drain diffusion region, reference numeral 110 denotes a source/drain silicide layer, reference numeral 117 denotes an SiO₂ gate insulating film, reference numeral 118 denotes an HfON gate insulating film, reference numeral 121 denotes an N+ polysilicon gate electrode and reference numeral 122 denotes a Pt silicide gate electrode.

In addition, Document 6 (International Electron Devices Meeting Technical Digest 2004, p. 91) discloses that it is possible to vary effective work functions by changing the composition ratio of Ni to Si of an NiSi gate on HfSiON. The abovementioned document shows a technique wherein by using NiSi₂ for the gate of the N-type MOSFET and Ni₃Si for the gate of the P-type MOSFET, as shown in FIG. 2d, the effective gate work functions of electrodes are changed to 4.4 eV and 4.8 eV, respectively. Note that in FIG. 2d, reference numeral 1 denotes a silicon substrate, reference numeral 2 denotes an element-isolating region, reference numeral 106 denotes an extended diffusion region, reference numeral 107 denotes a gate sidewall, reference numeral 108 denotes a source/drain diffusion region, reference numeral 110 denotes a source/drain silicide layer, reference numeral 117 denotes an SiO₂ gate insulating film, reference numeral 118 denotes an HfON gate insulating film, and reference numerals 123 and 124 denote Ni silicide gates.

In addition, according to Patent Publication 1 (Japanese Patent Laid-Open No. 2005-85949), silicide electrodes having work functions suited for N- and P-type MOSFETs are formed by forming groove portions by gate sidewalls and a silicon layer, depositing metal whose work function is smaller than that of intrinsic silicon in the N-type MOSFET region and metal whose work function is larger than that of intrinsic silicon in the P-type MOSFET region, and letting the metal react with the silicon layer, as shown in FIG. 2e. In this technique, it is stated that by thinning the silicon layer, it is possible to simultaneously achieve both the full silicidation of gate electrodes and the formation of silicides in the source/drain diffusion region. Note that in FIG. 2e, reference numeral 1 denotes a silicon substrate, reference numeral 2 denotes an element-isolating region, reference numeral 3 denotes a gate insulating film, reference numeral 9 denotes an extended diffusion region, reference numeral 10 denotes a gate sidewall, reference numerals 13 and 14 denote silicide electrodes, reference numeral 19 denotes a source/drain diffusion region, reference numeral 20 and 21 denote source/drain silicide layers, and reference numeral 111 denotes an insulating film.

However, the above-described related arts respectively have the problems noted below.

First, a dual metal gate technology for separately producing metal or alloys of different types having different work functions requires a process of etching away a layer deposited on the gate of either a P-type MOSFET or an N-type MOSFET. The technology hence has the problem that the quality of a gate insulating film degrades at the time of this etching, thus impairing the characteristics and the reliability of a device.

Second, as described in Document 5, the technique to modulate “Vth” using a silicide gate doped with an impurity has the problem that the gate electrode work function cannot be controlled if a high-dielectric constant material is used for the gate insulating film.

Third, in a technique to separately form an N+ polysilicon gate for an N-type MOSFET and a PtSi gate for a P-type MOSFET, it is possible to suppress polysilicon gate depletion and, therefore, the characteristics of the MOSFET can be improved since silicide electrodes are used in the P-type MOSFET. In the N-type MOSFET, however, the technique has the problem that it is not possible to suppress gate depletion and, therefore, the characteristics of the MOSFET cannot be improved since conventional polysilicon electrodes are used.

Fourth, a technique wherein PtSi (Pt:Si=10:1) is used for a P-type MOSFET has the problem that silicided portions are also etched away in a selective etching process of selectively removing only the unreacted metal portion after silicidation, thus making selective etching infeasible, since the composition ratio of metal in the silicide is too high.

Fifth, although a technique to have work functions modulated by separately forming Ni₃Si for the P-type MOSFET and NiSi₂ for the N-type MOSFET is effective since effective work functions can be controlled on high-dielectric constant gate oxide films, the technique is insufficient in terms of device characteristics and reliability.

Sixth, a method of simultaneously achieving both the full silicidation of gate electrodes and the silicidation of a source/drain diffusion region by thinning the silicon layer used in the above-described technique is also insufficient in terms of device characteristics and reliability.

### DISCLOSURE OF THE INVENTION

In view of the above-described problems of the related arts, it is an object of the present invention to provide a semiconductor device having improved device characteristics and reliability.

An semiconductor device in accordance with an aspect of the present invention includes: a first field effect transistor region including a gate insulating film, a gate electrode and gate sidewalls formed in a P channel forming region on a semiconductor substrate; and a second field effect transistor region including a gate insulating film, a gate electrode and gate sidewalls formed in an N channel forming region on the semiconductor substrate, wherein in the first and second field effect transistor regions, the gate electrodes are composed primarily of a silicide of metal M represented as M(x)Si(1−x)(0<x<1) and satisfy t1−t2<L/2, wherein the height of the gate electrodes is t1, the height of the gate sidewalls is t2 and the gate length of the gate electrodes is L; and the height of the gate electrode in the P channel forming region is greater than the height of the gate electrode in the N channel forming region.

In the semiconductor device in accordance with another aspect of the present invention, it is preferable to satisfy t1−t2<0, wherein the height of the gate electrodes is t1 and the height of the gate sidewalls is t2.

In the semiconductor device in accordance with another aspect of the present invention, the height of the gate electrode in the N channel forming region is preferably less than half the height of the gate electrode in the P channel forming region.

In the semiconductor device in accordance with another aspect of the present invention, the gate insulating film preferably contains a metal oxide containing an A element made of Hf or Zr and a B element made of Si or Al, or a metal oxynitride selected from these metal oxides containing nitrogen. More preferably, the mole fraction (A/(A+B)) of the A and B elements in the metal oxide or the metal oxynitride is no smaller than 0.3 but no larger than 0.7.

In the semiconductor device in accordance with another aspect of the present invention, the gate insulating film preferably has a laminated structure including a silicon dioxide film or a silicon oxynitride film, and a layer containing Hf or Zr.

In the semiconductor device in accordance with another aspect of the present invention, the gate electrodes are preferably composed primarily of a silicide of metal M represented as M(x)Si(1−x)(0<x<1) at least in portions in contact with the gate insulating film, and have regions wherein 0.6<x<0.8 holds true for the silicide contained in a gate electrode in the P channel forming region and 0.3<x<0.55 holds true for the silicide contained in a gate electrode in the N channel forming region.

In the semiconductor device in accordance with another aspect of the present invention, the metal M is preferably capable of being silicided using a salicide process and, more preferably, the metal M is Ni or Pt.

In the semiconductor device in accordance with another aspect of the present invention, the metal M is preferably Ni or Pt, and the gate electrodes are preferably composed primarily of a silicide of the metal M represented as M(x)Si(1−x)(0<x<1) at least in portions in contact with the gate insulating film, and contain regions wherein 0.7<x<0.8 holds true for the silicide contained in the gate electrode in the P channel forming region and 0.45<x<0.55 holds true for the silicide contained in the gate electrode in the N channel forming region.

In the semiconductor device in accordance with another aspect of the present invention, the gate electrode in the P channel forming region preferably contains a silicide region containing an M₃Si phase as a primary constituent at least in portions in contact with the gate insulating film, and the gate electrode in the N channel forming region preferably contains a silicide region containing an MSi phase or an MSi₂ phase as a primary constituent at least in portions in contact with the gate insulating film.

It should be noted that in this specification, the term “high-dielectric constant (high-k)” is used to discriminate from a insulating film made of silicon dioxide (SiO₂) which has been commonly used as a gate insulating film and only means that it is, in a general sense, higher than the dielectric constant of a silicon dioxide and thus the specific value of the high dielectric constant is not defined in particular.

According to the present invention, by using silicides for gate electrodes, it is possible to not only avoid gate electrode depletion but also prevent the reliability degradation of an insulating film due to strains caused by silicide electrodes. It is also possible to suppress the mobility degradation of an NMOSFET due to the strain of channel Si caused by the silicide electrodes, and to realize the improved mobility of a PMOSFET.

In addition, it is possible to achieve the following improvement effects in a manufacturing process:

(1) Control can be carried out so that a silicide layer does not protrude above gate sidewalls after silicidation or in the course of silicidation reaction, thereby preventing the increase of particles due to shape anomaly.

(2) Since the exposure of the side surfaces of gates is prevented, the instability of metal composition control due to a supply of metal from the gates' side surfaces is improved.

As a result, it is possible to improve the performance and reliability of a metal gate CMOSFET wherein a full-silicidation technique is used.

### BRIEF DESCRIPTION OF THE DRAWINGS

FIG. 1 is a cross-sectional view of a semiconductor device in accordance with an exemplary embodiment of the present invention;

FIG. 2a is a cross-sectional view of a conventional semiconductor device;

FIG. 2b is another cross-sectional view of a conventional semiconductor device;

FIG. 2c is yet another cross-sectional view of a conventional semiconductor device;

FIG. 2d is still another cross-sectional view of a conventional semiconductor device;

FIG. 2e is still another cross-sectional view of a conventional semiconductor device;

FIG. 3 is a schematic view intended to explain the mechanism of silicide formation;

FIG. 4 is a schematic view intended to explain the mechanism of strain formation;

FIG. 5 is a graphical view illustrating the relationship between the mobility of electrons and holes and the height of silicides;

FIG. 6 is another graphical view illustrating the relationship between the mobility of electrons and holes and the height of silicides;

FIG. 7 is a cross-sectional process drawing intended to explain a manufacturing method in accordance with a first exemplary embodiment of the present invention;

FIG. 8 is a cross-sectional process drawing intended to explain a manufacturing method in accordance with a second exemplary embodiment of the present invention;

FIG. 9 is a cross-sectional process drawing intended to explain a manufacturing method in accordance with a third exemplary embodiment of the present invention;

FIG. 10 is a graph showing the relationship between the defect of a gate insulating film and the height of silicides;

FIG. 11 is a schematic view illustrating the mechanism of strain formation;

FIG. 12 is a graph intended to explain the mechanism of strain formation;

FIG. 13 is another graph intended to explain the mechanism of strain formation;

FIG. 14 is another schematic view intended to explain the mechanism of strain formation;

FIG. 15 is a graph showing the dependence of a drain current on the gate voltage of an FET fabricated in accordance with an exemplary embodiment of the present invention;

FIG. 16 is a graph showing the mobility of electrons and holes of an FET fabricated in accordance with an exemplary embodiment of the present invention; and

FIG. 17 is a graph showing the result of evaluating the reliability of an FET fabricated in accordance with an exemplary embodiment of the present invention.

### BEST MODE FOR CARRYING OUT THE INVENTION

Hereinafter, the present invention will be described in detail according to the exemplary embodiments thereof.

If a MOSFET having a metal gate that uses a silicide material is formed, an extremely large stress is induced in a gate insulating film and in a channel forming region, thereby affecting the reliability of the insulating film and the mobility of the channel region. This stress depends on the height of silicide electrodes. Hence, the present invention is based on the principle that the excellent operation of a CMOS is achieved by controlling this height of silicide electrodes.

The above-described phenomenon, if explained by taking as an example the case where an Ni silicide film is used as the gate electrode, stems from the cubical expansion of polysilicon that occurs when polysilicon is reacted with Ni and thereby silicided. In the formation of the gate electrode using a full silicidation technique, the metal Ni is deposited in an opening above a polysilicon surrounded by a gate insulating film and gate sidewalls, and the entire region up to the interface of the gate insulating film is silicided by heating. At this time, the polysilicon expands and the volume thereof increases due to the introduction of Ni. Since the gate electrode is surrounded by the gate insulating film and the gate sidewalls, the polysilicon increases its volume upwardly toward the opening. In addition, stresses are induced in the gate sidewalls and in the gate insulating film. Silicidation with Ni progresses as Ni diffuses into the polysilicon at the interface between the polysilicon and Ni, as shown in FIG. 3. The Ni silicide thus formed is pushed upwardly and, as a result, shaped into such a columnar form as shown in FIG. 3.

Due to such a process of silicide formation as described above, two types of strain are applied to the silicide electrode.

A first strain is caused by the presence of unreacted metal Ni in the silicide formation process.

The volume of the formed Ni silicide is smaller than the sum of the volume of the metal Ni consumed for silicidation and the volume of the reacted polysilicon itself. In a case where the metal Ni is supplied from the upper surface of the polysilicon, the Ni silicide rises in such a manner as to displace the volume of the consumed Ni metal.

However, if the upper surface of the Ni silicide protrudes upwardly from the upper ends of the gate sidewalls and thus the side surfaces of the Ni silicide become exposed, the metal Ni is also supplied from the side surfaces of the Ni silicide. Consequently, the amount of rise of the Ni silicide becomes larger compared with the volume of the metal Ni consumed at the upper surface. Since unreacted Ni metal exists on the Ni silicide, as noted above, the expansion of the Ni silicide is suppressed by the unreacted metal Ni on the Ni silicide, if the amount of rise of the Ni silicide becomes larger than the volume of the metal Ni consumed at the upper surface of the Ni silicide. As a result, an extremely large stress acts on the gate sidewalls and the gate insulating film. The inventor et. al discovered that if t1−t2>L/2 holds true assuming that the height of the gate electrode is t1, the height of the gate sidewalls is t2, and the gate length is L, the reliability of the gate insulating film extremely degrades due to the large stress.

This is because the amount of Ni introduced from the side surface of the silicide becomes dominant since the side surface area of the silicide becomes larger than the upper surface area thereof in the full silicidation process and a large stress acts on the gate insulating film due to the above-described mechanism. Accordingly, in order to ensure the reliability of the gate insulating film, it is necessary to adjust the height of the gate sidewalls and polysilicon so that t1−t2<L/2 holds true. Preferably, t1−t2<0 holds true, which means the silicide is lower than the gate sidewalls. In this case, there is no diffusion of Ni from the side surfaces of the silicide and, therefore, there is no possibility of stresses arising due to the above-described mechanism of greatly impairing the reliability of the gate insulating film.

On the other hand, even if t1−t2<L/2 is satisfied, a second strain acts on channel portions due to the cubical expansion of polysilicon along with silicidation. This strain works so as to decrease electron mobility and increase hole mobility. In addition, a strain arising in the channel portions has dependence on the height of the silicide and a larger strain arises in the channel portions with the increase in the height of the silicide. Accordingly, in order to suppress a decrease in the mobility of an N channel MOSFET and to increase the mobility of a P channel MOSFET, it is important to decrease the height of the silicide gate electrode on the N channel and increase the height of the silicide gate electrode on the P channel to the extent of not exceeding the above-noted limits in the relationship with the gate sidewalls.

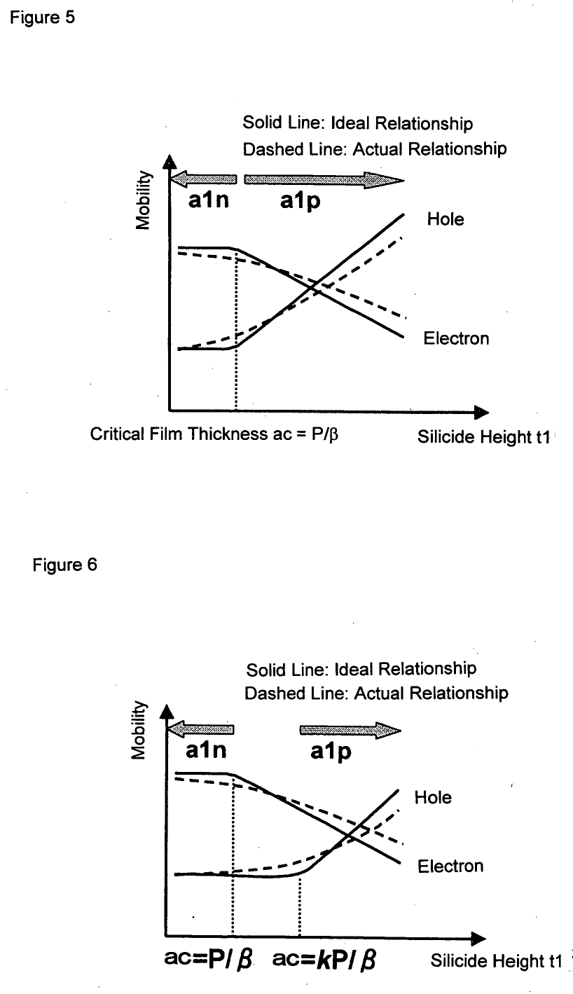

The fundamental principle of occurrence of the second strain when the above-noted condition t1−t2<L/2 is satisfied is probably explained as follows. That is, strain release can be achieved by releasing a volume change due to silicidation as a change in film thickness. If a volume-changing pressure surpasses the force to suppress a change in film thickness at this time, a change in film thickness takes place. Since the force to suppress the film thickness change depends on adhesive strength “β” between the sidewall insulating film and the silicide already formed at that time, as shown in FIG. 4, the force is proportional to silicide film thickness a1 and can therefore be represented as “β*a1”. Assuming that a volume-expanding pressure at the time of silicidation is “P”, then the critical film thickness “ac” (=P/β) of silicide electrodes at which the volume change can be released as a film thickness change is obtained. Under the condition “a1≦ac”, the strain is released by the volume change. It is therefore desirable to avoid mobility degradation by letting the height “a1n” of the full-silicide gate electrode satisfy “a1n≦ac”, as shown in FIG. 5, in the case of the NMOSFET. On the other hand, since mobility improvement can be expected more when the strain is not released in the case of the PMOSFET, it is preferable to improve mobility by letting the height “a1p” of the full-silicide gate electrode satisfy “a1p>ac”. Accordingly, it is desired that the height “a1p” of the PMOSFET gate electrode be greater than the height “an” of the NMOSFET gate electrode. In an actual device, however, it is not possible to obtain a definite value of critical film thickness “ac” since cubical expansion progresses even while the force to suppress the expansion is at work, as shown by dashed lines in FIG. 5. It is therefore important to satisfy the relational expression “a1p>a1n”.

Particularly in such a case where the ratio of metal in the silicide composition of the PMOSFET is higher than that in the silicide composition used for the NMOSFET and the silicide for the PMOSFET is “k” times the silicide for the NMOSFET in terms of the volume ratio when the same amount of Si is contained, the volume-expanding pressure is “k” times as high as on the PMOSFET side than on the NMOSFET side. Thus, in order to prevent a strain on the PMOSFET side from being released, it is desirable that “a1p>k*ac” holds true, as shown in FIG. 6. Accordingly, it can be said that the relational expression “a1p>k*a1n” preferably holds true in this case. If Ni₃Si is used for the PMOSFET and NiSi for the PMOSFET, it is desirable that the relational expression “t1p>2*t1n” holds true, which means the height of the silicide electrode for the NMOSFET is less than half the height of the silicide electrode for the PMOSFET.

In the present invention, it is preferable to use metal with which polysilicon (poly-Si) can be completely silicided at low temperatures as the metal for forming gate electrodes. Specifically, it is preferable to use metal which can be silicided within the temperature range from 350 to 500° C. which does not cause the resistance value of a metal silicide formed in the contact region of a source/drain diffusion region to increase. It is also preferable to use metal with which both a crystal phase having a high Si concentration and a crystal phase having a high metal concentration can be formed within the above-noted temperature range. By siliciding the poly-Si electrodes using such metal as described above, it is possible to determine the composition of the electrodes in a self-aligned manner, as well as to suppress process variations. From the above-described point of view, Ni or Pt is preferred as the metal M for silicidation. This is because poly-Si can be completely silicided with Ni or Pt by annealing at 450° C. or lower and because crystal phases can be controlled in a step-by-step manner by simply changing the amount of metal M supplied.

The composition of the metal M silicides forming the gate electrodes, when represented as M(x)Si(1−x)(0<x<1), preferably satisfies 0.6<x<0.8 in the case of the metal M silicide used for the gate electrode of the P-type MOSFET and satisfies 0.3<x<0.55 in the case of the metal M silicide used for the gate electrode of the N-type MOSFET, at least in portions in contact with the gate insulating film, preferably on the side of a region in contact with a high-k insulating film. This is because the crystal phases of metal silicides are classified primarily into MSi₂, MSi, M₃Si₂, M₂Si and M₃Si and a mixture of these crystal phases can also be formed according to the heat history thereof. The silicide used for the gate electrode of the P-type MOSFET preferably contains an M₃Si phase as its major constituent and the silicide used for the gate electrode of the N-type MOSFET preferably contains an MSi phase or an MSi₂ phase as its major constituent. In the case of silicides having metal ratios whose “x” is 0.8 or larger, the silicide portion is easy to be also etched in a selective etching process of selectively removing only the unreacted metal portion after silicidation, thereby causing selective etching to be difficult to carry out. Silicides having metal ratios whose “x” is 0.3 or smaller are less metallic and are more likely to induce gate depletion. As even more preferred values, “x” preferably satisfies 0.7<x<0.8 in the case of the metal M silicide used for the gate electrode of the P-type MOSFET and satisfies 0.45<x<0.55 in the case of the metal M silicide used for the gate electrode of the N-type MOSFET. That is, the silicide used for the gate electrode of the P-type MOSFET preferably contains an M₃Si phase as its major constituent and the silicide used for the gate electrode of the N-type MOSFET preferably contains an MSi phase as its major constituent.

In a case where such silicide metal electrodes as described above are used, a metal oxide containing an A element of Hf or Zr and a B element of Si or Al is preferred for a high-k insulating film to be used as the gate insulating film. More preferably, a metal oxynitride formed by introducing nitrogen into these metal oxides is used in place of the metal oxide. This is because the crystallization of the high-k insulating films is suppressed by the introduction of nitrogen, thereby improving the reliability of the CMOSFET. In addition, it is desirable that the mole fraction (A/(A+B) of the A and B elements in the metal oxide or the metal oxynitride is no smaller than 0.3 but no larger than 0.7. With this range, a “Vth” value of +0.35 V necessary for low-power CMOS devices can be obtained. More desirably, the mole fraction (A/(A+B) of the A and B elements in the metal oxide or the metal oxynitride is no smaller than 0.4 but no larger than 0.6. With this range, a “Vth” value of ±0.3 V necessary for even higher speed CMOS devices can be obtained.

The gate insulating film to be used in the present invention preferably has a laminated structure composed of a silicon dioxide film or a silicon oxynitride film and of the above-noted high-k insulating film. Consequently, it is possible to obtain even superior device characteristics.

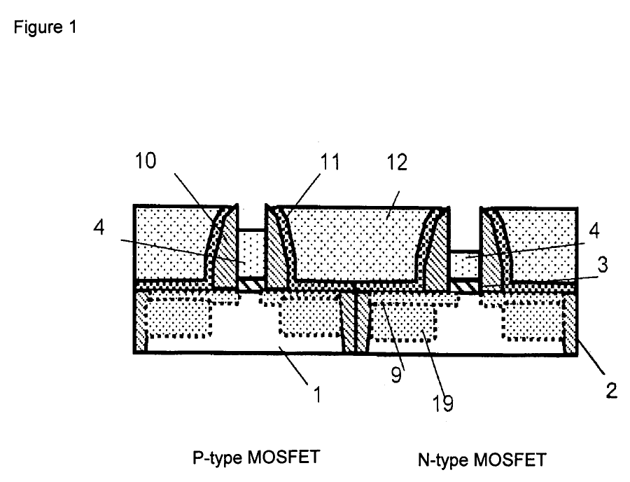

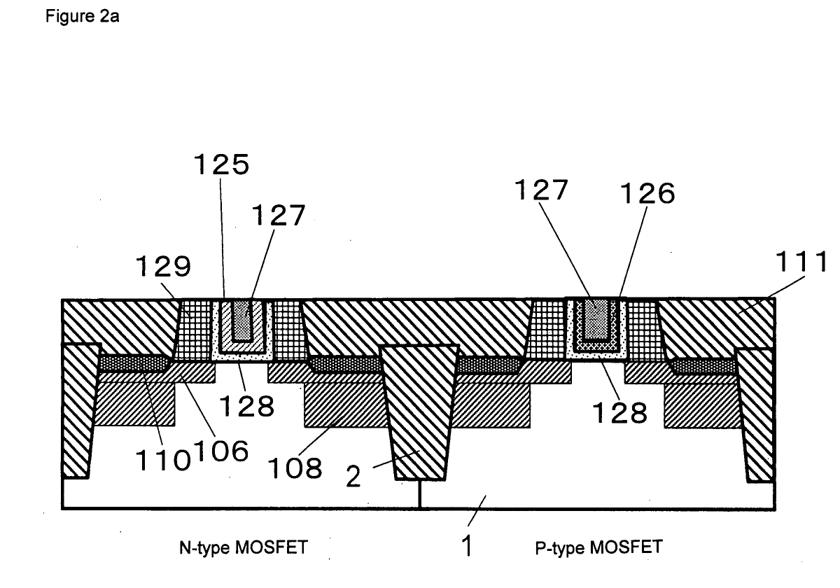

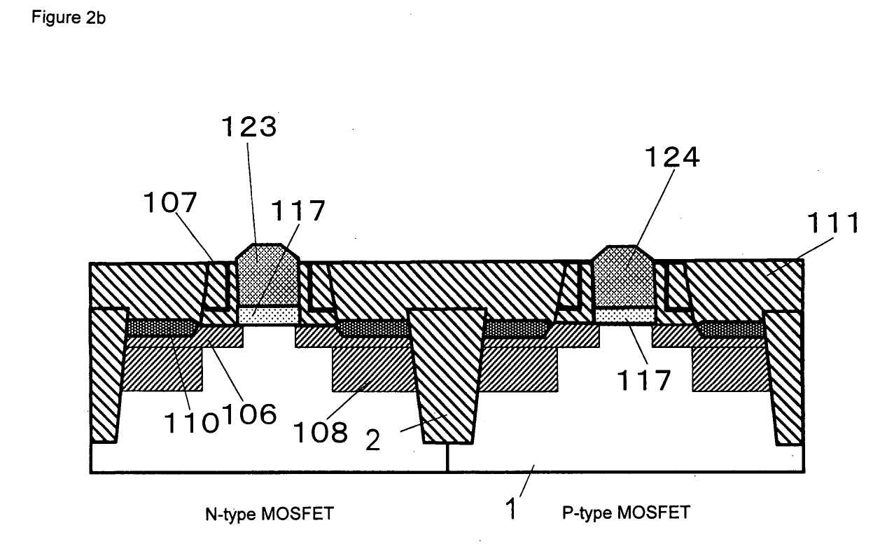

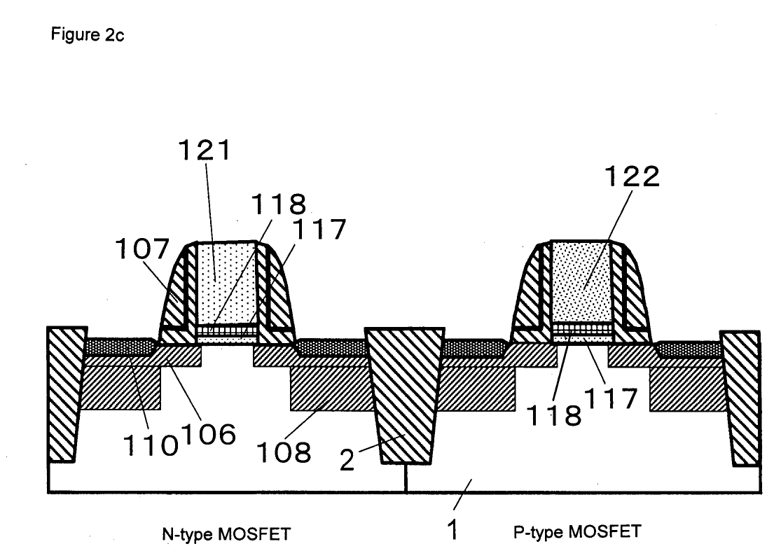

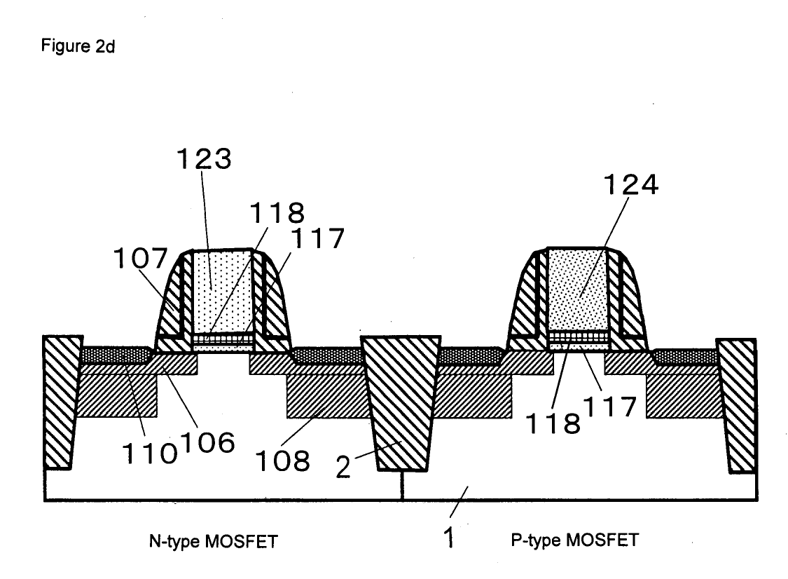

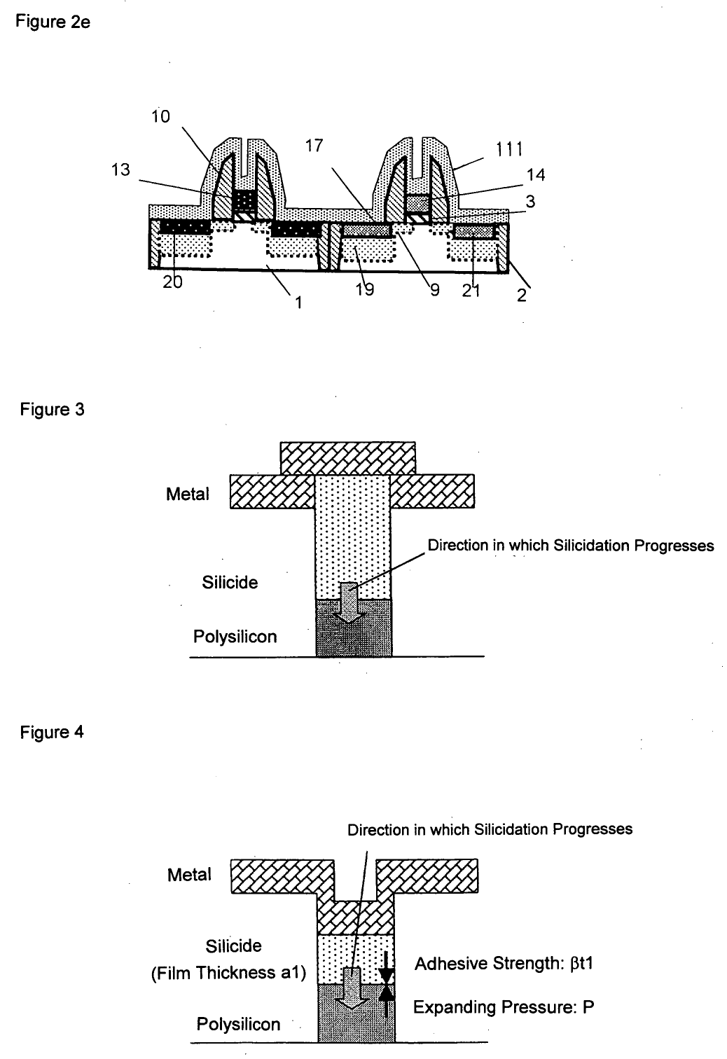

FIG. 1 is a structural drawing of an exemplary embodiment of the above-described CMOS transistor, wherein reference numeral 1 denotes a silicon substrate, reference numeral 2 denotes an element-isolating region, reference numeral 3 denotes a gate insulating film, reference numeral 4 denotes a gate electrode, reference numeral 9 denotes an extended diffusion region, reference numeral 10 denotes a gate sidewall, reference numeral 11 denotes an etch stop layer, reference numeral 12 denotes an interlayer insulating film, and reference numeral 19 denotes a source/drain diffusion region.

According to the above-described structure, it is possible to not only inhibit a decrease in the drain current of a transistor due to the depletion of conventionally used poly-Si electrodes but also prevent the reliability degradation of the insulating film due to strains caused by silicide electrodes. It is also possible to prevent the mobility degradation of the NMOSFET due to strains in the channel Si caused by the silicide electrodes and enhance the mobility of the PMOSFET.

In addition, it is possible achieve the following improvement effects in a manufacturing process:

(1) Control can be carried out so that a silicide layer does not protrude above gate sidewalls after silicidation or in the course of silicidation reaction, thereby preventing the increase of particles due to shape anomaly.

(2) Since the exposure of the side surfaces of gates is prevented, the instability of metal composition control due to a supply of metal from the gates' side surfaces is improved.

Note that in the explanation given above, no reference has been made to the composition of the gate electrodes and to the distribution of crystal phases in the depth direction. This is because the “Vth” of the MOSFETs is determined by the combination of a gate insulating film and gate electrodes in contact therewith. Accordingly, as long as the constituent elements, composition and crystal phase of a portion where the gate electrodes and the gate insulating film contact with each other satisfy the conditions provided in the present invention, it is still possible to obtain the advantages provided by the present invention even if the constituent elements or crystal phase of a portion not in contact with the gate insulating film is different or even if the gate electrodes have a compositional change along the depth direction thereof.

Hereinafter, exemplary embodiments of the present invention will be described with reference to the accompanying drawings.

### FIRST EXEMPLARY EMBODIMENT

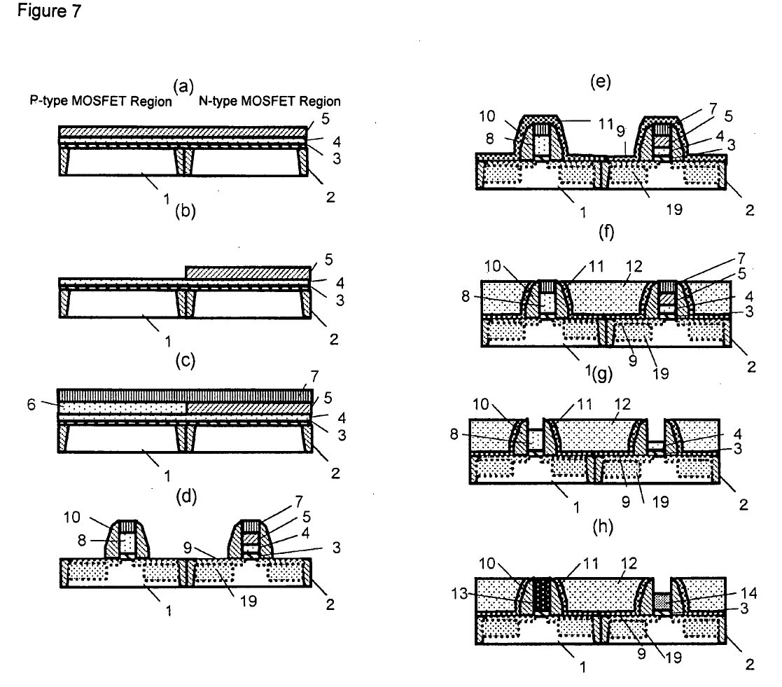

Now, a method of manufacturing semiconductor devices in accordance with an exemplary embodiment of the present invention will be described using FIGS. 7(a) to 7(k).

First, an element-isolating region 2 is formed in the surface region of a silicon substrate 1 using a shallow trench isolation (STI) technique, as shown in FIG. 7(a). Then, after carrying out ion implantation and activation for the purpose of forming channel forming regions on the silicon substrate, there is formed a gate insulating film 3. As the gate insulating film, it is possible to use a metal oxide film, a metal silicate film, a high-k insulating film formed by introducing nitrogen into the metal oxide or metal silicate, a silicon dioxide film, or a silicon oxynitride film. Among these films, there is preferred a silicon dioxide film, a silicon oxynitride film, or a high-k insulating film made of a metal oxide film or a metal oxynitride film containing Hf or Zr. This is because these films are not only stable against high-temperature heat treatment but also easily available as films having less fixed charges therein. In addition, in a case where a high-k insulating film is used, a silicon dioxide film or a silicon oxynitride film may be inserted between the high-k insulating film and the silicon substrate, in order to reduce the interface state at the interface between the silicon substrate and the gate insulating film and further reduce the effect of fixed charges in the high-k insulating film. As the high-k insulating film, an HfSiON film is more preferred.

Next, a first silicon layer 4 and a first sacrificial insulating film 5 are formed on the gate insulating film 3. As the first silicon layer 4, it is possible to deposit polysilicon using a chemical vapor deposition (CVD) process. Amorphous silicon may be deposited in place of the polysilicon. In addition, this deposition may be carried out using a sputtering process. As a material for the first sacrificial insulating film 5, it is possible to use a material wherewith a selection ratio can be secured with respect to gate sidewalls 10 or a sacrificial interlayer insulating film 12 in a subsequent removal step.

Next, as shown in FIG. 7(b), the first sacrificial insulating film 5 in the P-type MOSFET region is removed using a lithography technique and an etching technique.

Next, after removing a natural oxide film on the first silicon layer 4 using fluorinated acid, silicon is selectively grown on the silicon layer 4 in the P-type MOSFET region by means of selective silicon growth, as shown in FIG. 7(c). Then, a second sacrificial insulating film 7 is deposited on the entire substrate surface. As a material for the second sacrificial insulating film, it is also possible to use a material wherewith a selection ratio can be secured with respect to the gate sidewalls 10 or the sacrificial interlayer insulating film 12 in a subsequent removal step. The same material as that of the first sacrificial insulating film 5 may be used.

Next, the P-type MOSFET region formed of the gate insulating film 3, the silicon layer 8 made of the first silicon layer 4 and the selectively-grown silicon layer 6, and the second sacrificial insulating film 7 and the N-type MOSFET region formed of the gate insulating film 3, the first silicon layer 4, the first sacrificial insulating film 5 and the second sacrificial insulating film 7 are processed into gate electrode shapes using a lithography technique and a reactive ion etching (RIE) technique.

Subsequently, ion implantation is carried out using a pattern obtained by processing the regions into gate electrode shapes as a mask, to form an extended diffusion region 9 in a self-aligned manner.

Next, at least one layer of an insulating film is deposited and then etched back to form gate sidewalls 10 (FIG. 7(d)).

Subsequently, ion implantation is carried out once again using the pattern of the gate electrode shapes and the gate sidewalls 10 as a mask, to form a source/drain diffusion region 19 through activation annealing.

Next, as shown in FIG. 7(e), an etch stop layer 11, which is a silicon nitride film here, is deposited on the entire substrate surface.

In addition, the sacrificial interlayer insulating film 12, which is a silicon dioxide film here, is formed using a normal-pressure CVD process and is planarized using a chemical mechanical polishing (CMP) technique. Then, the upper portion of the etch stop layer 11 is exposed by etching back, and then the exposed etch stop layer is selectively etched to expose the second sacrificial insulating film 7 above the gate electrode shape pattern (FIG. 7(f)).

Next, as shown in FIG. 7(g), the first sacrificial insulating film 5 and the second sacrificial insulating film 7 are removed using etching conditions selective with respect to the sacrificial interlayer insulating film 12. As a result, it is possible to obtain silicon layers which differ in height between the N-type MOSFET region and the P-type MOSFET region but are lower than the upper end of the gate sidewalls 10 in either of the two regions.

The thickness of the second sacrificial insulating film 7 in the P-type MOSFET and the sum of the thicknesses of the first sacrificial insulating film Sand the second sacrificial insulating film 7 in the N-type MOSFET region directly equal the depth of a groove portion formed by the gate sidewalls after the removal of these films. Accordingly, the thicknesses of the first sacrificial insulating film 5 and the second sacrificial insulating film 7 are previously set so that the depth of the groove portion is greater than a value determined by “the amount of change (increment) due to the silicidation of the silicon layers−(maximum gate length/2)”. For example, in a case where a 100 nm-high Ni₃Si full silicide electrode is to be formed in the P-type MOSFET region, the thickness of the silicon layer is previously set to 46.5 nm and the sum of the thicknesses of the first sacrificial insulating film 5 and the second sacrificial insulating film 7 is previously set to at least 53.5 nm, since the volume of the silicon layer expands by a factor of 2.15 due to silicidation into Ni₃Si.

Next, as shown in FIG. 7(h), the silicon layers 8 and 4 are completely silicided to form a first silicide electrode 13 and a second silicide electrode 14. Metal to be used for the silicidation of the silicon layers 8 and 4 can be selected from Ni, Pt, Hf, V, Ti, Ta, W, Co, Cr, Zr, Mo and Nb or from their alloys and the like. Different metal constituents or different impurity ions are introduced into the silicide electrodes 13 and 14, respectively, so that the electrodes undergo work function control. In a case where the gate insulating film is an oxide film or an oxynitride film, it is possible to obtain silicide electrodes having work functions respectively suited for the N-type MOSFET and the P-type MOSFET, by carrying out silicidation reaction after implanting P, As or Sb into the silicon layer for the N-type MOSFET and B, Al or Ga into the silicon layer for the P-type MOSFET. In a case where a high-k insulating film is contained in the gate insulating film, it is also possible to obtain silicide electrodes having work functions respectively suited for the N-type MOSFET and the P-type MOSFET, by making the metal composition ratio of the silicide electrode of the P-type MOSFET higher than that of the silicide electrode of the N-type MOSFET. Particularly in a case where a gate insulating film containing HfSiON or HfSiO is used, it is possible to obtain work functions respectively optimal for the N-type MOSFET and the P-type MOSFET, by using NiSi or NiSi₂ for the gate of the N-type MOSFET and Ni₃Si for the gate of the P-type MOSFET. Composition control can be achieved by controlling the amount of deposited metal and the film thickness of the silicon layer. However, if the silicon layer protrudes above the gate sidewalls, there takes place an oversupply of metal due to the bypassing of metal from the side surface of the protuberant gate electrode particularly in the case of a short gate length. In this case, it is no longer possible to obtain silicide electrodes having a desired composition particularly for a short gate length. In the case of the present exemplary embodiment, however, it is possible to prevent the bypassing of metal from the side surfaces of the gate electrodes, thereby obtaining desired work functions, since the side surfaces of the silicon layer are not exposed.

In addition, in a case where the method of manufacturing the semiconductor device of the present exemplary embodiment is used, it is possible to form silicides of different metal compositions by one process each of metal deposition and heat treatment by controlling the silicon film thicknesses of the N-type MOSFET and P-type MOSFET regions. For example, the height of the silicon layer in the N-type MOSFET region is previously set to 30 nm and the height of the silicon layer in the P-type MOSFET region is previously set to 20 nm for an Ni sputtering amount of 30 nm, when forming NiSi in the N-type MOSFET and Ni₃Si in the P-type MOSFET by one process each of Ni sputtering and heat treatment. Consequently, it is possible to form both the NiSi and Ni₃Si silicides at one time by heat treatment in a 300 to 500° C. nitrogen atmosphere. At this time, the heights of the finished NiSi and Ni₃Si are 33 nm and 43 nm, respectively.

### SECOND EXEMPLARY EMBODIMENT

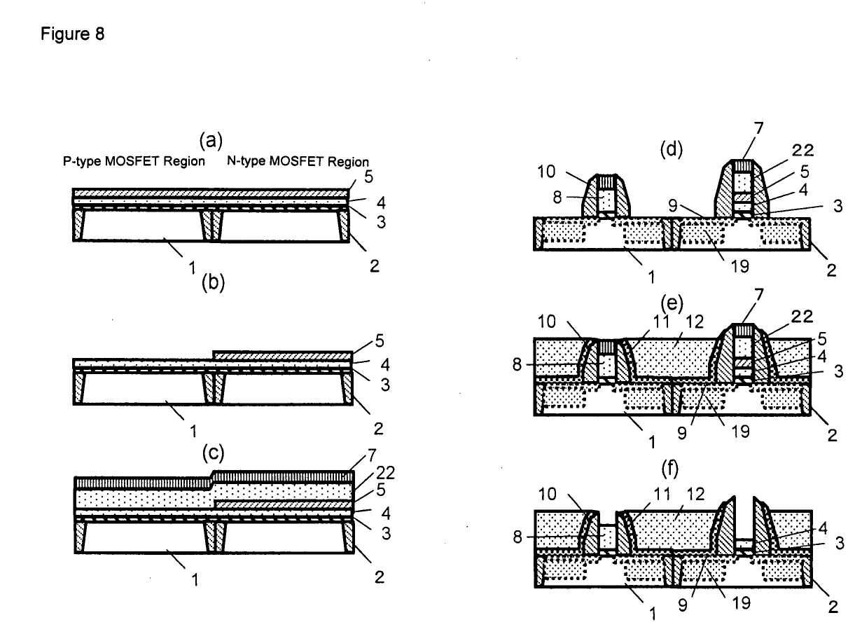

Now, another method of manufacturing semiconductor devices in accordance with an exemplary embodiment of the present invention will be described using FIGS. 8(a) to 8(f).

First, an element-isolating region 2 is formed in the surface region of a silicon substrate 1, as shown in FIG. 8(a). Then, after carrying out ion implantation and activation for the purpose of forming channel forming regions on the silicon substrate, there is formed a gate insulating film 3. Next, a first silicon layer 4 and a first sacrificial insulating film 5 are formed on the gate insulating film 3.

Next, as shown in FIG. 8(b), the first sacrificial insulating film 5 in the P-type MOSFET region is removed using a lithography technique and an etching technique.

Next, after removing a natural oxide film on the first silicon layer 4 using fluorinated acid, a second silicon layer 22 is deposited in the N-type MOSFET and P-type MOSFET regions using a CVD process or a sputtering process, as shown in FIG. 8(c). Then, a second sacrificial insulating film 7 is deposited.

Next, the P-type MOSFET region formed of the gate insulating film 3, the silicon layer 8 made of the first silicon layer 4 and the second silicon layer 22, and the second sacrificial insulating film 7 and the N-type MOSFET region formed of the gate insulating film 3, the first silicon layer 4, the first sacrificial insulating film 5, the second silicon layer 22 and the second sacrificial insulating film 7 are processed into gate electrode shapes using a lithography technique and an RIE technique.

Subsequently, ion implantation is carried out using a pattern obtained by processing the MOSFETs into gate electrode shapes as a mask, to form an extended diffusion region 9 in a self-aligned manner.

Next, at least one layer of an insulating film is deposited and then etched back to form gate sidewalls 10 (FIG. 8(d)).

Subsequently, ion implantation is carried out once again using the gate electrode shape pattern and the gate sidewalls 10 as a mask, to form a source/drain diffusion region 19 through activation annealing.

Next, an etch stop layer 11, which is a silicon nitride film here, is deposited on the entire substrate surface. In addition, the sacrificial interlayer insulating film 12, which is a silicon dioxide film here, is formed using a normal-pressure CVD process and is planarized using a CMP technique. Then, the upper portion of the etch stop layer 11 is exposed by etching back, and then the exposed etch stop layer is selectively etched to expose the second sacrificial insulating film 7 above the gate electrode shape pattern (FIG. 8(e)).

Next, by masking the N-type MOSFET region with a resist and removing the second sacrificial insulating film 7 and by masking the P-type MOSFET region with a resist and successively removing the second sacrificial insulating film 7, the second silicon layer 22 and the first sacrificial insulating film 5, it is possible to form the silicon layer 8 and the silicon layer 4 different in height from each other, as shown in FIG. 8(f).

Next, by completely siliciding the silicon layers 8 and 4 according to the method described in the first exemplary embodiment, it is possible to obtain a MOSFET structure in accordance with an exemplary embodiment of the present invention.

### THIRD EXEMPLARY EMBODIMENT

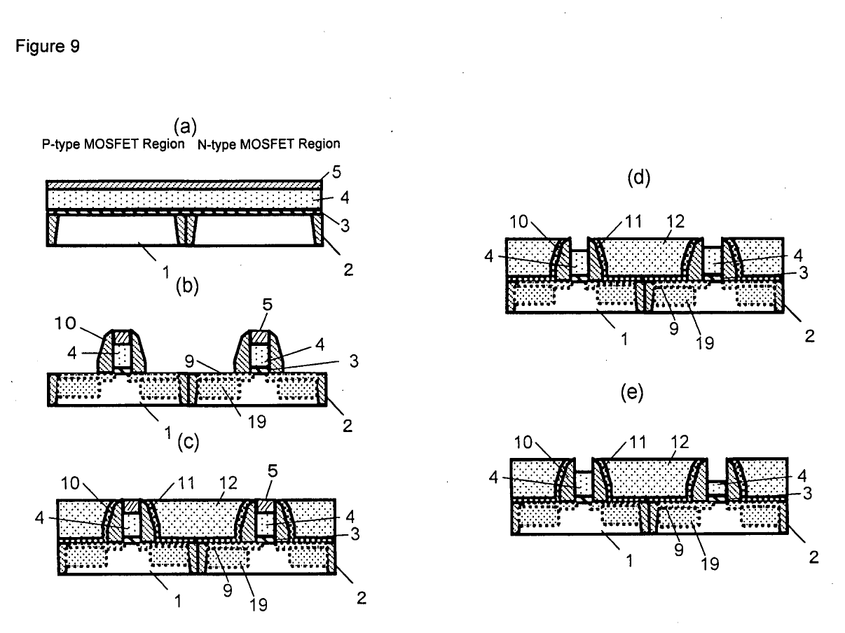

Now, another method of manufacturing semiconductor devices in accordance with an exemplary embodiment of the present invention will be described using FIGS. 9(a) to 9(e).

First, an element-isolating region 2 is formed in the surface region of a silicon substrate 1, as shown in FIG. 9(a). Then, after performing ion implantation and activation for the purpose of forming channel forming regions on the silicon substrate, there is formed a gate insulating film 3. Next, a first silicon layer 4 and a first sacrificial insulating film 5 are formed on the gate insulating film 3.

Next, the gate insulating film 3, the first silicon layer 4 and the first sacrificial insulating film 5 are processed into gate electrode shapes using a lithography technique and an RIE technique.

Subsequently, ion implantation is carried out using a pattern shaped in gate electrode shapes as a mask, to form an extended diffusion region 9 in a self-aligned manner.

Next, at least one layer of an insulating film is deposited and then etched back to form gate sidewalls 10 (FIG. 9(b)).

Subsequently, ion implantation is carried out once again using the gate electrode shape pattern and the gate sidewalls 10 as a mask, to form a source/drain diffusion region 19 through activation annealing.

Next, an etch stop layer 11, which is a silicon nitride film here, is deposited on the entire substrate surface. In addition, the sacrificial interlayer insulating film 12, which is a silicon dioxide film here, is formed using a normal-pressure CVD process and is planarized using a CMP technique. Then, the upper portion of the etch stop layer 11 is exposed by etching back, and then the exposed etch stop layer is selectively etched to expose the first sacrificial insulating film 5 above the gate electrode shape pattern (FIG. 9(c)).

Next, the first sacrificial insulating film 5 is removed as shown in FIG. 9(d).

Next, by masking the N-type MOSFET region with a resist and etching back the silicon layer 4 by a predetermined thickness and by masking the P-type MOSFET region with a resist and etching back the silicon layer 4 by a predetermined thickness, it is possible to form the silicon layers 4 different in height from each other between the N-type MOSFET and the P-type MOSFET, as shown in FIG. 9(e).

Next, by completely siliciding the silicon layers 4 according to the method described in the first exemplary embodiment, it is possible to obtain a MOSFET structure in accordance with an exemplary embodiment of the present invention.

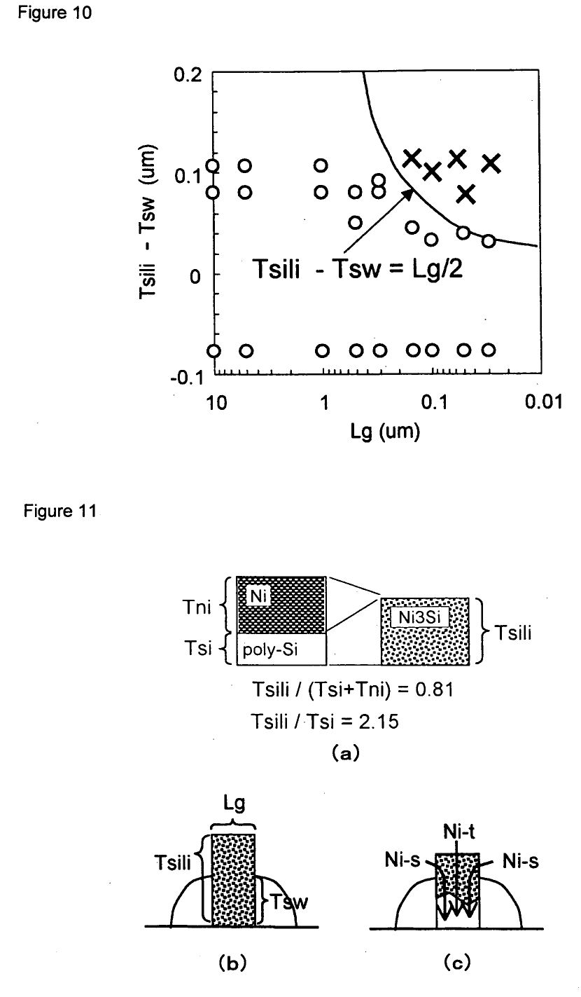

FIG. 10 shows the relationship of the difference (Tsili−Tsw) between the height “Tsw” of gate sidewalls and the height “Tsili” of a silicide electrode with the gate length (Lg), with regard to an Ni₃Si electrode wherein a defective gate insulating film occurred in the full silicidation process of a transistor actually prototyped. In the figure, each circle (∘) denotes a good transistor whereas each christcross (X) denotes a transistor with a defective gate electrode. As shown in FIG. 10, it is understood that gate electrode formation failures occurred in a domain beyond a boundary line represented by “Tsili−Tsw=Lg/2”. Thus, it is necessary to control the height of the Ni₃Si electrode protruding above the gate sidewalls and satisfy Tsili−Tsw<Lg/2”, in order to improve the yield of an Ni silicide gate transistor.

In a case where an Ni₃Si electrode is formed, the height “Tsili” of Ni₃Si is 2.15 times the height “Tsi” of polysilicon prior to full silicidation, as shown in FIG. 11(a). For this reason, the Ni₃Si electrode formed by full silicidation is shaped to protrude above the gate sidewalls, as shown in FIG. 11(b), if the height of initial polysilicon is the same as that of the gate sidewalls. In a shape where the silicide electrode protrudes above the gate sidewalls, Ni is supplied into the polysilicon not only from the uppermost surface of the gate electrode but also from the side surface of the gate protruding above the gate sidewalls, as shown in FIG. 11(c).

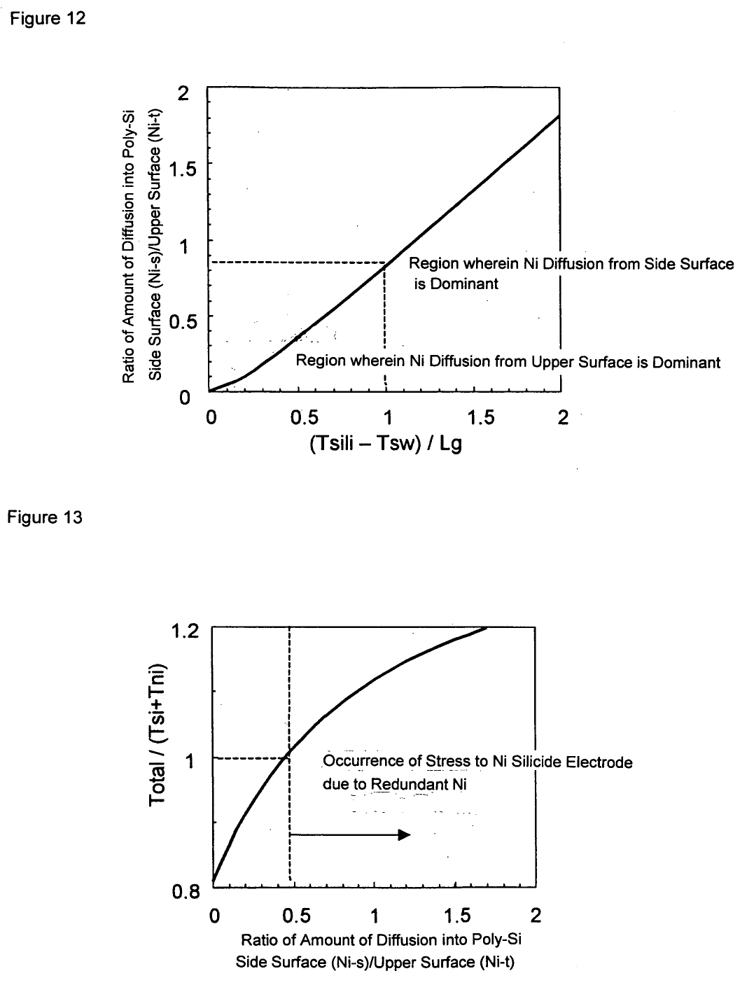

FIG. 12 is a graph wherein the ratio of the amount of Ni (Ni-s) supplied from the side surfaces of the gate to the amount of Ni supplied from the uppermost surface of the gate is plotted with respect to (Tsili−Tsw)/Lg. Here, “Tsili” denotes the height of the silicide electrode, “Tsw” denotes the height of the gate sidewalls and “Lg” denotes the gate length. This graph reveals that Ni supply from the side surfaces of the gate becomes dominant as the value of “Tsili−Tsw” becomes larger than “Lg”. In this case, Ni immediately above the gate electrode deposited in order to form Ni₃Si remains as is, without being consumed in the polysilicon. As a result, cubical expansion when the polysilicon changes into Ni₃Si is suppressed by the redundant Ni, thereby causing the problem that a stress arises in the silicide electrode.

FIG. 13 shows a change in the height of an upper surface immediately above the electrode including the redundant Ni before and after silicidation with respect to a change in the ratio of the amount supplied (ratio of the amount of diffusion: side surface (Ni-s)/upper surface (Ni-t)), in a case where Ni is supplied to the polysilicon from both the upper surface and the side surfaces of the gate. Here, “Ttotal” denotes the height of an upper surface immediately above the electrode including the redundant Ni, “Tni” denotes the thickness of Ni on an upper surface of the gate electrode necessary to form Ni₃Si, and “Tsi” denotes the thickness of polysilicon. From FIG. 13, it is understood that if the ratio (Ni-s/Ni-t) of the amount of Ni diffusion into polysilicon exceeds 0.5, the height of an upper surface immediately above the electrode after silicidation becomes greater than the thickness of pre-silicidation polysilicon and Ni combined. This is because the amount of Ni supplied from the side surfaces of the gate protruding above the gate sidewalls increases and Ni deposited immediately above the gate is no longer consumed, as shown in FIG. 11(c).

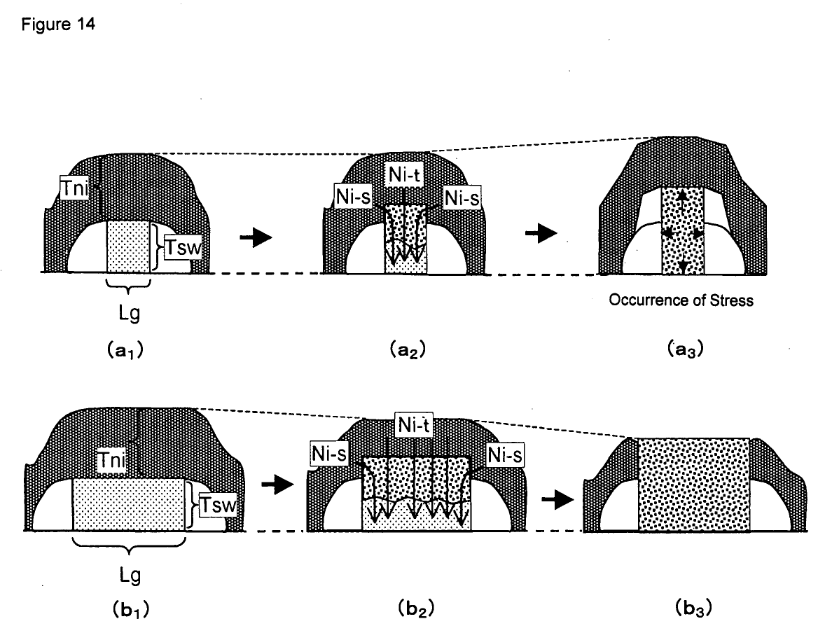

FIG. 14 schematically illustrates this phenomenon. FIGS. 14(a1), 14(a2) and 14(a3) are for a case where “Tsili−Tsw>Lg/2” holds true, showing a condition in which silicidation progresses in this order. FIGS. 14(b1), 14(b2) and 14(b3) are for a case where “Tsili−Tsw<Lg/2” holds true, showing a condition in which silicidation progresses in this order.

As shown in FIGS. 14(a1), 14(a2) and 14(a3), in a case where (Ni-s/Ni-t)>0.5, cubical expansion toward the upside of the gate electrode is suppressed by Ni left over immediately above the gate electrode without being supplied to polysilicon in the course of a silicidation process, thereby causing a large stress in directions toward the gate sidewalls and the substrate.

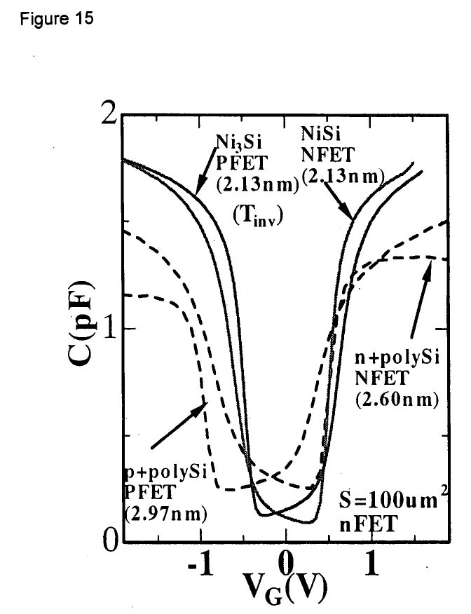

FIG. 15 shows the voltage dependence of the drain current in FETs wherein HfSiON is used for the gate insulating film, NiSi₂ is used for the gate electrode of the N-type MOSFET and Ni₃Si is used for the gate electrode of the P-type MOSFET. The height of the gate sidewalls is 100 nm, the height of the silicide electrode of the PMOSFET is 80 nm, and the height of the silicide electrode of the NMOSFET is 40 nm. Consequently, it is understood that the “Vth” of the N-type and P-type MOS transistors is suited for low-power CMOS devices. The dotted curve in the figure shows the result of using polysilicon (poly-Si) for the gate electrodes for comparison purposes.

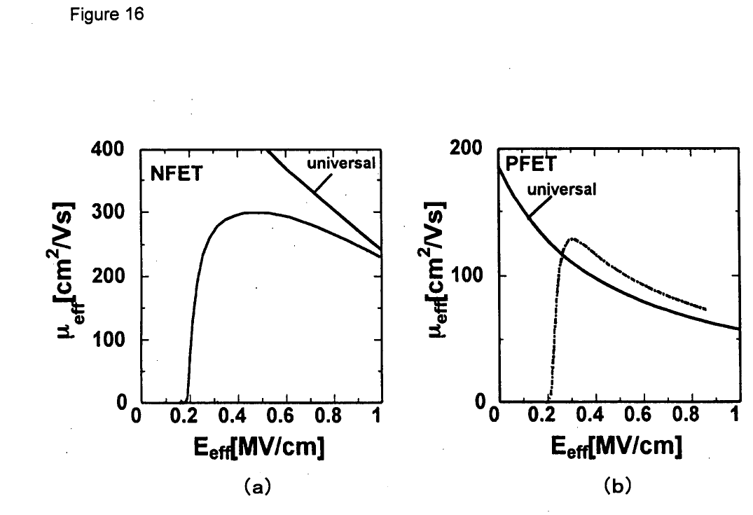

FIG. 16 is a graphical view wherein the mobility of the same MOSFET as noted above is compared between an NMOSFET (FIG. 16(a)) and a PMOSFET (FIG. 16(b)). It is understood that whereas electron mobility virtually agrees with the ideal curve, hole mobility has been improved to an extent beyond the ideal curve due to the effect of strain from the silicide electrode.

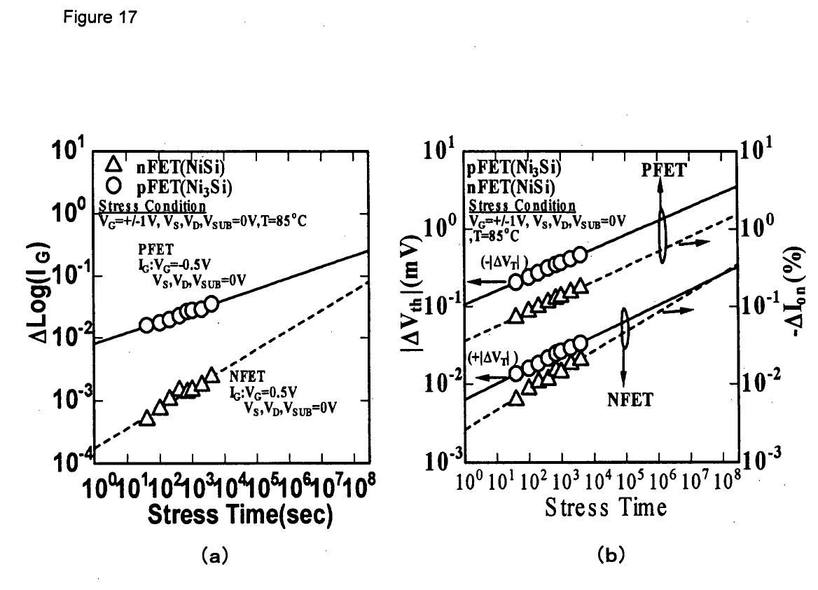

FIG. 17 is a graphical view wherein (a) gate leak current and (b) amounts of VT and ION degradations are predicted from the result of evaluating the positive bias temperature instability (PBTI) and the negative bias temperature instability (NBTI) of the same MOSFET as noted above. Positive and negative stress biases were applied respectively to the NFET and the PFET at 85° C. Measurement showed that the predicted increases of leak current 10 years later were as small as 0.1 digits and 0.2 digits respectively for the NFET and PFET. In addition, the amounts of change in [VT, 10N] were [0.3 mV, 0.3%] and [3.2 mV, 1.5%] respectively for the NFET and PFET, which were at levels low enough to enable products to be assured.

As described above, according to the structure of the present invention having combinations of the heights of silicide electrodes shown in the present exemplary embodiment, it is understood that excellent transistor characteristics can be obtained.

Having thus described the exemplary embodiments of the present invention, it is to be understood that the present invention is not restricted to the foregoing exemplary embodiments; rather, the present invention may be carried out by selecting materials and structures as appropriate, without departing from the subject matter of the present invention. For example, if any metal hard to silicide under relatively low temperatures is used for a combination of metal elements for siliciding gate electrodes and metal elements used to silicide sources/drains, it is possible to achieve predetermined silicidation by carrying out heat treatment for a comparatively long period of time. This is because there is the need for carrying out silicidation under temperatures at which the alteration of source/drain silicides does not take place. By adjusting the conditions of heat treatment temperature, time and the like according to the metal elements used, it is possible to obtain a structure whereby desired advantages are available. In addition, by making such contrivances as replacing poly-Si used as a gate material with amorphous Si or adjusting the film-forming temperature of metal for silicidation, it is also possible to carry out silicidation at relatively low temperatures. By concurrently using these techniques as necessary, it is possible to realize desired combinations of metal elements.

1-11. (canceled)

12. A semiconductor device comprising:
a first field effect transistor region comprising a gate insulating film, a gate electrode and gate sidewalls formed in a P channel forming region on a semiconductor substrate; and
a second field effect transistor region comprising a gate insulating film, a gate electrode and gate sidewalls formed in an N channel forming region on the semiconductor substrate,
wherein in the first and second field effect transistor regions,
the gate electrodes are composed primarily of a silicide of metal M represented as M(x)Si(1−x)(0<x<1);
the gate electrodes satisfy t1−t2<L/2, wherein the height of the gate electrodes is t1, the height of the gate sidewalls is t2 and the gate length of the gate electrodes is L; and
the height of the gate electrode in the P channel forming region is greater than the height of the gate electrode in the N channel forming region.

13. The semiconductor device according to claim 12, wherein t1−t2<0 is satisfied, wherein the height of the gate electrodes is t1 and the height of the gate sidewalls is t2.

14. The semiconductor device according to claim 12, wherein the height of the gate electrode in the N channel forming region is less than half the height of the gate electrode in the P channel forming region.

15. The semiconductor device according to claim 12, wherein the gate insulating film contains a metal oxide containing an A element made of Hf or Zr and a B element made of Si or Al, or a metal oxynitride selected from these metal oxides containing nitrogen.

16. The semiconductor device according to claim 15, wherein the mole fraction (A/(A+B)) of the A and B elements in the metal oxide or the metal oxynitride is no smaller than 0.3 but no larger than 0.7.

17. The semiconductor device according to claim 12, wherein the gate insulating film has a laminated structure comprising a silicon dioxide film or a silicon oxynitride film, and a layer containing Hf or Zr.

18. The semiconductor device according to claim 12, wherein the gate electrodes are composed primarily of a silicide of metal M represented as M(x)Si(1−x)(0<x<1) at least in portions in contact with the gate insulating film, and have regions wherein 0.6<x<0.8 holds true for the silicide contained in a gate electrode in the P channel forming region and 0.3<x<0.55 holds true for the silicide contained in a gate electrode in the N channel forming region.

19. The semiconductor device according to claim 12, wherein the metal M is capable of being silicided using a salicide process.

20. The semiconductor device according to claim 12, wherein the metal M is Ni or Pt.

21. The semiconductor device according to claim 12, wherein the metal M is Ni or Pt, and the gate electrodes are composed primarily of a silicide of the metal M represented as M(x)Si(1−x)(0<x<1) at least in portions in contact with the gate insulating film, and contain regions wherein 0.7<x<0.8 holds true for the silicide contained in the gate electrode in the P channel forming region and 0.45<x<0.55 holds true for the silicide contained in the gate electrode in the N channel forming region.

22. The semiconductor device according to claim 20, wherein
the gate electrode in the P channel forming region contains a silicide region containing an M₃Si phase as a primary constituent at least in portions in contact with the gate insulating film, and
the gate electrode in the N channel forming region contains a silicide region containing an MSi phase or an MSi₂ phase as a primary constituent at least in portions in contact with the gate insulating film.
